(19) United States
(12) Patent Application Publication
(10) Pub. No.: US 2007/0042298 A1
(43) Pub. Date: Feb. 22, 2007

(54) Method for manufacturing semiconductor device using immersion lithography process

(75) Inventors: Jae Chang Jung, Seoul (KR); Sung Koo Lee, Seoul (KR); Keun Do Ban, Gyeonggi-do (KR); Cheol Kyu Bok, Gyeonggi-do (KR); Seung Chan Moon, Gyeonggi-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyunggi-do (KR)

(21) Appl. No.: 11/481,299

(22) Filed: Jul. 5, 2006

(30) Foreign Application Priority Data
Aug. 17, 2005 (KR) 10-2005-0075419

(51) Int. Cl. G03F 7/26

(52) U.S. Cl. 430/311

(57) ABSTRACT

Disclosed is a method for manufacturing a semiconductor device using an immersion lithography process comprising rapidly accelerating the rotation of a wafer after exposing and before developing steps to remove an immersion lithography solution, thereby effectively reducing water mark defects.

### BACKGROUND OF THE DISCLOSURE

1. Field of the Disclosure

This disclosure relates to a method for manufacturing a semiconductor device using an immersion lithography process. More specifically, it relates to a method for manufacturing a semiconductor device which can solve the problems of water mark defects effectively in the course of an immersion lithography process.

2. Description of the Related Technology

Recently, pattern sizes have become smaller in accordance with the smaller semiconductor devices. Research has been focused on developing exposers and corresponding photoresist materials to obtain these fine patterns. Although KrF (248 nm) and ArF (193 nm) have widely been used as exposure light sources, efforts to use light sources having shorter wavelengths such as F₂ (157 nm) or EUV (13 nm) and to increase numerical apertures of lenses have been made.

However, new exposers are required when the light sources become changed to have shorter wavelengths, making it ineffective in terms of the manufacturing cost. Also, although the increase of numerical apertures can result in the increase of resolution power, it will decrease the size of the depth of focus.

Recently, an immersion lithography process has been developing in order to solve these problems. While a dry exposure process utilizes air having a refractive index of 1.0 as a medium for exposure beams between an exposure lens and a wafer having a photoresist film, the immersion lithography process utilizes H₂O or an organic solvent having a refractive index of more than 1.0. This enables the immersion lithography process to obtain the same effect as when a light source of a shorter wavelength is used, or as when a lens having a higher numerical aperture is used, without decrease of depth of focus.

The immersion lithography process improves the depth of focus remarkably, and enables the formation of a finer pattern even when the exposure light source of the same wavelength is used.

However, the immersion lithography process has the problem of generating water mark defects, such as that shown in FIG. 1, in the course of the process. As a result, it is difficult to apply the immersion lithography process to the actual industrial process.

### SUMMARY OF THE DISCLOSURE

Disclosed herein is a method for manufacturing a semiconductor device which reduces water mark defects generated from an immersion lithography process.

### BRIEF DESCRIPTION OF THE DRAWINGS

For more complete understanding of the invention, reference should be made to the following detailed description and accompanying drawings wherein:

FIG. 1 is a scanning electron micrograph (SEM) showing a water mark defect generated from a conventional immersion lithography process.

The specification, drawings and examples are intended to be illustrative, and are not intended to limit this disclosure to the specific embodiments described herein.

### DETAILED DESCRIPTION

Provided herein is a method for manufacturing a semiconductor device using an immersion lithography process comprising rapidly accelerating the rotation of a wafer to remove an immersion lithography solution after exposing and before developing steps. Preferably, the method further comprises rapid deceleration of the rotation of the wafer after the rapid acceleration thereof.

Preferably, the rapid acceleration may be accomplished by accelerating the wafer at about 3,000 rpm per second to about 15,000 rpm per second to reach a speed of about 4,000 rpm to about 6,000 rpm, and then the wafer can be rotated at that speed for about 10 seconds to about 50 seconds. The rapid deceleration may preferably be accomplished by decelerating the rotation of the wafer at about 3,000 rpm per second to about 15,000 rpm per second. In one embodiment of the method, the rapid deceleration will substantially slow the rotation of the wafer. In another embodiment of the method, the rapid deceleration will substantially stop the rotation of the wafer. In another embodiment of the method, the rapid deceleration will stop the rotation of the wafer.

Preferably, the rapid acceleration may be accomplished by accelerating the wafer at about 8,000 rpm per second to about 12,000 rpm per second to reach a speed of about 4,000 rpm to about 6,000 rpm, and then the wafer can be rotated at that speed for about 10 seconds to about 20 seconds. The rapid deceleration preferably may be accomplished by decelerating the rotation of the wafer at about 8,000 rpm per second to about 12,000 rpm per second.

The sequence of rapid acceleration and rapid deceleration preferably is repeated, and can be repeated more than one time, preferably 2, 3 or 4 times.

Water mark defects are scarcely prevented when the acceleration or the deceleration is less than about 3,000 rpm per second, and a rotation motor may be damaged when it is accelerated or decelerated more than about 15,000 rpm per second.

Specifically, a method for manufacturing a semiconductor device can comprise the steps of:

(a) forming a photoresist film over an underlying layer on a wafer;

(b) exposing the wafer using an exposer for immersion lithography;

(c) rapidly accelerating the rotation of the wafer to remove an immersion lithography solution; and

(d) developing the resulting wafer to obtain a photoresist pattern.

Preferably, an organic bottom anti-reflection film is formed over the underlying layer before the photoresist film is formed in the step (a). In addition, an organic top anti-reflection film preferably is formed over the photoresist film before the exposing step (b).

As described above, the method may further comprise rapidly decelerating the rotation of the wafer after rapidly accelerating thereof in the step (c). The sequence of rapid acceleration and then rapid deceleration preferably is performed more than one time.

Although any photoresist composition can be used in the above-described process, chemically amplified photoresist compositions are preferably used. The exposer preferably uses KrF or ArF as exposure lights.

The pattern may comprise one or both of a line/space pattern and a hole pattern, for example.

The disclosed method will be described in detail by referring to specific examples below, which are not intended to limit the invention.

In the examples, 1400i produced by ASML company was used for an exposer for immersion lithography, and water mark defects were observed by a Stells defect measuring device produced by KLA company. The results were shown by a total number of the water mark defects in the 8 inch wafer.

### COMPARATIVE EXAMPLE 1

### Pattern Formation by a Conventional Method (1)

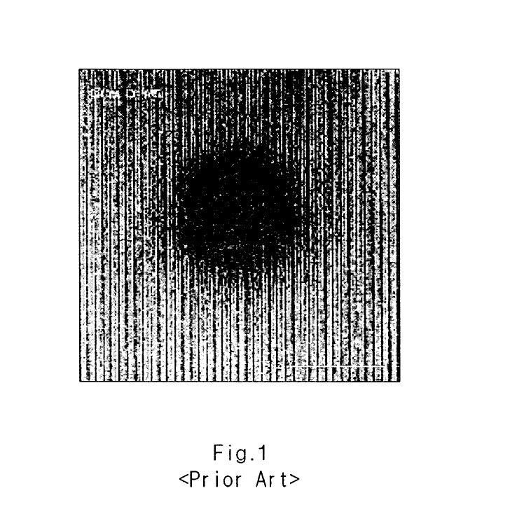

A bottom anti-reflection composition (A25 BARC produced by Dongjin Semichem Co.) was coated over a wafer, and ArF photoresist (X121 produced by Shinetsu Co.) was coated thereon to a thickness of 0.17 μm. The wafer was soft-baked at 130° C. for 90 seconds. After exposing the wafer by an immersion lithography process, the wafer was accelerated at 2,000 rpm per second to reach a speed of 5,000 rpm. After that the wafer was rotated at 5,000 rpm for about 2 minutes to remove water, an immersion solution. Next, the resulting wafer was post-baked at 130° C. for 90 seconds. After developing it in 2.38 wt. % TMAH aqueous solution, about 2,000 water mark defects as shown in FIG. 1 were observed.

### COMPARATIVE EXAMPLE 2

### Pattern Formation by a Conventional Method (2)

A bottom anti-reflection composition (A25 BARC produced by Dongjin Semichem Co.) was coated over a wafer, and ArF photoresist (X121 produced by Shinetsu Co.) was coated thereon to a thickness of 0.17 μm. The wafer was soft-baked at 130° C. for 90 seconds. A top anti-reflection composition (ARC 20 produced by Nitsan Chemistry Co.) was coated over the photoresist film, and then baked at 90° C. for 60 seconds. After exposing the wafer by an immersion lithography process, the wafer was accelerated at 2,000 rpm per second to reach a speed of 5,000 rpm. After that the wafer was rotated at 5,000 rpm for about 2 minutes to remove water. Next, the resulting wafer was post-baked at 130° C. for 90 seconds. After developing it in 2.38 wt. % TMAH aqueous solution, about 140 water mark defects as shown in FIG. 1 were observed.

The water mark defects observed in Comparative Examples 1 and 2 were presumed to be circular bridges generated in a region where water remains, because the temperature of the region was not raised in the baking step after exposure due to the high specific heat of water.

### EXAMPLE 1

### Pattern Formation by a Present Method (1)

A bottom anti-reflection composition (A25 BARC produced by Dongjin Semichem Co.) was coated over a wafer, and ArF photoresist (X121 produced by Shinetsu Co.) was coated thereon to a thickness of 0.17 μm. The wafer was soft-baked at 130° C. for 90 seconds. After exposing the wafer by an immersion lithography process, water was removed by rapid acceleration and deceleration of the wafer. For the rapid acceleration and deceleration, (1) the wafer was accelerated at 10,000 rpm per second to reach a speed of 5,000 rpm and then rotated at that speed for about 30 seconds, and (2) the wafer was decelerated at 10,000 rpm per second to stop the rotation. The steps (1) and (2) were repeated 1, 2, 3 or 4 times, respectively. Next, the resulting wafer was post-baked at 130° C. for 90 seconds. After developing it in 2.38 wt. % TMAH aqueous solution, a photoresist pattern was obtained. Table 1 shows the number of resulting water mark defects.

### EXAMPLE 2

### Pattern Formation by a Present Method (2)

The same procedure of Example 1 was repeated except that (1) the wafer was accelerated at 2,000 rpm per second to reach a speed of 3,000 rpm and then rotated at that speed for about 30 seconds, and (2) the wafer was decelerated at 2,000 rpm per second to stop the rotation. Table 1 shows the number of resulting water mark defects.

### EXAMPLE 3

### Pattern Formation by a Present Method (3)

The same procedure of Example 1 was repeated except that (1) the wafer was accelerated at 10,000 rpm per second to reach a speed of 5,000 rpm and then rotated at that speed for about 10 seconds, and (2) the wafer was decelerated at 10,000 rpm per second to stop the rotation. Table 1 shows the number of resulting water mark defects.

### EXAMPLE 4

### Pattern Formation by a Present Method (4)

A bottom anti-reflection composition (A25 BARC produced by Dongjin Semichem Co.) was coated over a wafer, and ArF photoresist (X121 produced by Shinetsu Co.) was coated thereon to a thickness of 0.17 μm. The wafer was soft-baked at 130° C. for 90 seconds. A top anti-reflection composition (ARC 20 produced by Nitsan Chemistry Co.) was coated over the photoresist film, and then baked at 90° C. for 60 seconds. After exposing the wafer by an immersion lithography process, water was removed by rapid acceleration and deceleration of the wafer. For the rapid acceleration and deceleration, (1) the wafer was accelerated at 10,000 rpm per second to reach a speed of 5,000 rpm and then rotated at that speed for about 30 seconds, and (2) the wafer was decelerated at 10,000 rpm per second to stop the rotation. The steps (1) and (2) were repeated 1, 2, 3 or 4 times, respectively. Next, the resulting wafer was post-baked at 130° C. for 90 seconds. After developing it in 2.38 wt. % TMAH aqueous solution, a photoresist pattern was obtained. Table 1 shows the number of resulting water mark defects.

### EXAMPLE 5

### Pattern Formation by a Present Method (5)

The same procedure of Example 4 was repeated except that (1) the wafer was accelerated at 2,000 rpm per second to reach a speed of 3,000 rpm and then rotated at that speed for about 30 seconds, and (2) the wafer was decelerated at 2,000 rpm per second to stop the rotation. Table 1 shows the number of resulting water mark defects.

### EXAMPLE 6

### Pattern Formation by a Present Method (6)

The same procedure of Example 4 was repeated except that (1) the wafer was accelerated at 10,000 rpm per second to reach a speed of 5,000 rpm and then rotated at that speed for about 10 seconds, and (2) the wafer was decelerated at 10,000 rpm per second to stop the rotation. Table 1 shows the number of resulting water mark defects.

TABLE 1

| | Number of water mark defects | | | | | |
|---|---|---|---|---|---|---|
| | Exam- | Exam- | Exam- | Exam- | | |
| | ple 1 | ple 2 | ple 3 | ple 4 | Example 5 | Example 6 |
| Repeated | 320 | 7511 | 370 | 63 | 2500 | 87 |
| 1 time | | | | | | |
| Repeated | 32 | 7632 | 38 | 7 | 2130 | 25 |
| 2 times | | | | | | |
| Repeated | 0 | 7570 | 14 | 0 | 2003 | 7 |
| 3 times | | | | | | |
| Repeated | 0 | 7320 | 6 | 0 | 1970 | 2 |
| 4 times | | | | | | |

As shown in Table 1, water mark defects were remarkably reduced when the acceleration and deceleration of the wafer was repeated just 2 times to remove an immersion solution. Especially, no water mark defects were observed when the acceleration and deceleration of the wafer was repeated 3 or more times.

As described above, a disclosed method for manufacturing a semiconductor device includes rapid acceleration and deceleration of the wafer after exposing and before developing steps, thereby reducing water mark defects remarkably.

What is claimed is:

1. A method for manufacturing a semiconductor device using an immersion lithography process, the improvement comprising rapidly accelerating the rotation of a wafer to reach a predetermined speed to remove an immersion lithography solution.

2. The method according to claim 1, further comprising rapidly decelerating the rotation of the wafer after the rapid acceleration thereof.

3. The method according to claim 1, wherein the rapid acceleration of the wafer is performed after exposing and before developing steps.

4. The method according to claim 1, wherein the rapid acceleration comprises accelerating the rotation of the wafer at about 3,000 rpm per second to about 15,000 rpm per second to reach a speed of about 4,000 rpm to about 6,000 rpm and rotating the wafer at said speed for about 10 seconds to about 50 seconds.

5. The method according to claim 4, wherein the rapid acceleration is repeated two or more times.

6. The method according to claim 5, wherein the rapid acceleration is repeated three or more times.

7. The method according to claim 2, wherein the rapid acceleration and deceleration comprises (i) rapidly accelerating the rotation of the wafer at about 3,000 rpm per second to about 15,000 rpm per second to reach a speed of about 4,000 rpm to about 6,000 rpm and rotating the wafer at said speed for about 10 seconds to about 50 seconds; and (ii) rapidly decelerating the rotation of the wafer at about 3,000 rpm per second to about 15,000 rpm per second.

8. The method according to claim 7, further comprising repeating the steps (i) and (ii) two or more times sequentially.

9. The method according to claim 8, comprising repeating the steps (i) and (ii) three or more times sequentially

10. The method according to claim 7, wherein the rapid acceleration and deceleration comprises (i) rapidly accelerating rotation of the wafer at about 8,000 rpm per second to about 12,000 rpm per second to reach a speed of about 4,000 rpm to about 6,000 rpm and rotating the wafer at said speed for about 10 seconds to about 20 seconds; and (ii) rapidly decelerating the rotation of the wafer at about 8,000 rpm per second to about 12,000 rpm per second.

11. A method for manufacturing a semiconductor device comprising the steps of:
(a) forming a photoresist film over an underlying layer on a wafer;
(b) exposing the wafer using an exposer for immersion lithography;
(c) rapidly accelerating the rotation of the wafer to remove an immersion lithography solution; and
(d) developing the resulting wafer to obtain a photoresist pattern.

12. The method according to claim 11, wherein the process further comprises the step of:
rapidly decelerating the rotation of the wafer after said rapidly accelerating step.

13. The method according to claim 11, wherein the rapid acceleration comprises accelerating the rotation of the wafer at about 3,000 rpm per second to about 15,000 rpm per second to reach a speed of about 4,000 rpm to about 6,000 rpm and rotating the wafer at said speed for about 10 seconds to about 50 seconds.

14. The method according to claim 12, wherein the rapid acceleration and deceleration comprises (i) rapidly accelerating the rotation of the wafer at about 3,000 rpm per second to about 15,000 rpm per second to reach a speed of about 4,000 rpm to about 6,000 rpm and rotating the wafer at said speed for about 10 seconds to about 50 seconds; and (ii) rapidly decelerating the rotation of the wafer at about 3,000 rpm per second to about 15,000 rpm per second.

15. The method according to claim 14, further comprising repeating the steps (i) and (ii) two or more times sequentially.

16. The method according to claim 15, comprising repeating the steps (i) and (ii) three or more times sequentially.

17. The method according to claim 11, wherein the photoresist pattern comprises one or both of a line/space pattern and a hole pattern.
